(19) United States
(12) Patent Application Publication
(10) Pub. No.: US 2020/0313103 A1
(43) Pub. Date: Oct. 1, 2020

(54) PATTERNING SEMICONDUCTOR FOR TFT DEVICE

(71) Applicant: Flexenable Limited, Cambridge (GB)

(72) Inventors: Herve VANDEKERCKHOVE, Cambridge (GB); Joffrey DURY, Cambridge (GB)

(21) Appl. No.: 16/651,626

(22) PCT Filed: Sep. 26, 2018
(86) PCT No.: PCT/EP2018/076103

§ 371 Date: Mar. 27, 2020

(30) Foreign Application Priority Data
Sep. 29, 2017 (GB) 1715794.2

(51) Int. Cl. H01L 51/05; H01L 27/28; H01L 51/00

(52) U.S. Cl. CPC H01L 51/052; H01L 51/0529; H01L 51/0017; H01L 27/283

(57) ABSTRACT

A technique, comprising: forming, over a substrate (2) comprising at least source and drain conductors (4, 6) for one or more transistor devices, at least a first, semiconductor layer (8) providing one or more semiconductor channels for the one or more transistor devices; forming, over the first layer, a second layer (10) that defines at least part of a gate dielectric for the one or more transistor devices; creating a pattern in the second layer, without depositing any temporary material onto the second layer; and using the pattern in the second layer to pattern the first layer.

A thin film-transistor (TFT) device may comprise a stack of layers defining the conductor, semiconductor and insulator elements of the TFT. The construction of the stack of layers may comprise depositing and patterning at least a semiconductor layer that provides a semiconductor channel of the TFT device.

A conventional technique for patterning a semiconductor layer in a top-gate TFT device involves forming a first gate dielectric layer over the semiconductor layer, depositing photoresist material over the first gate dielectric layer; patterning the deposited photoresist material; using the patterned resist as a protective mask to pattern both the semiconductor layer and the first gate dielectric layer together; and chemically stripping away the patterned resist before continuing to construct the stack by forming a second gate dielectric layer over the first gate dielectric layer, and forming a conductor pattern over the second gate dielectric layer, which conductor pattern defines at least a gate conductor of the TFT device.

The inventors for the present application have conducted research into further improving TFT performance, and have found that TFT performance can be improved by not using a photoresist technique to pattern the semiconductor via the first gate dielectric layer. The inventors for the present application attribute this improvement in TFT performance to an improvement in the interface between the first and second gate dielectric layers.

There is hereby provided a method, comprising: forming, over a substrate comprising at least source and drain conductors for one or more transistor devices, at least a first, semiconductor layer providing one or more semiconductor channels for the one or more transistor devices; forming, over the first layer, a second layer that defines at least part of a gate dielectric for the one or more transistor devices; creating a pattern in the second layer, without depositing any temporary material onto the second layer; and using the pattern in the second layer to pattern the first layer.

According to one embodiment, creating a pattern in the second layer comprises: exposing the second layer to an image of the pattern to create a solubility pattern in the second layer, the solubility pattern defining differences in solubility in a first solvent between different regions of the second layer; and using said first solvent to develop the solubility pattern and create a physical pattern in said second layer.

According to one embodiment, the pattern in the second layer to pattern the first layer comprises using a plasma treatment.

According to one embodiment, said exposing the second layer to an image of the pattern comprises exposing the second layer to a positive image of the pattern using radiation that decreases the solubility of the second layer in exposed regions.

According to one embodiment, said exposing the second layer to an image of the pattern comprises exposing the second layer to a positive image of the pattern using radiation of a wavelength that initiates a cross-linking reaction in said second layer in exposed regions.

According to one embodiment, the method comprises forming at least one further insulating layer over the patterned, second layer; and forming over the at least one further insulating layer at least a gate conductor pattern defining at least gate conductors for the one or more transistor devices.

According to one embodiment, forming said gate conductor pattern comprises depositing conductor material onto the at least one further insulating layer through a shadow mask.

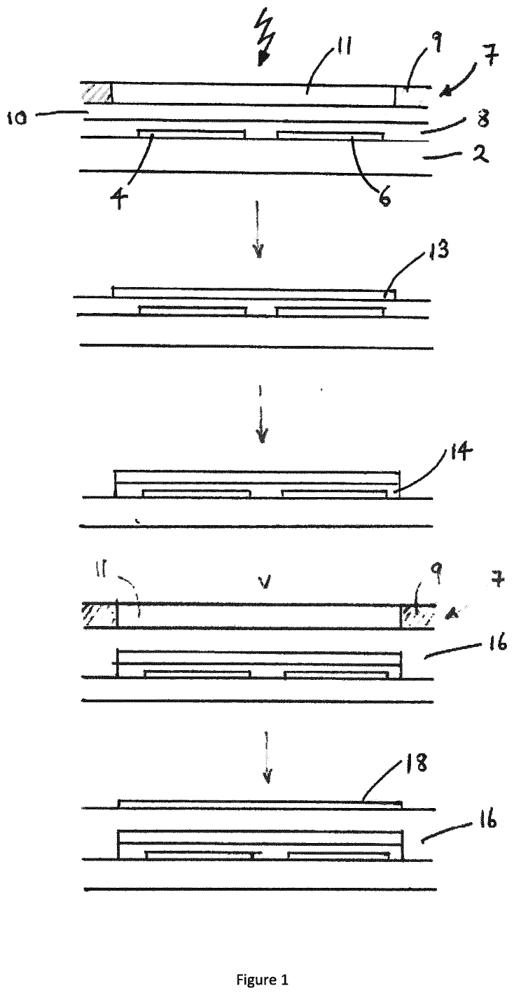

An embodiment of the present invention is described hereunder, with reference to the accompanying FIG. 1, which illustrates an example of a method according to an embodiment of the present invention;

FIG. 1 shows the production of a single TFT device, but the method is equally applicable to the production of an array of TFT devices. In one example embodiment, the technique is used for the production of an organic transistor device (such as an organic thin film transistor (OTFT) device) for the control component for e.g. an organic liquid crystal display (OLCD) device. OTFTs comprise an organic semiconductor (such as e.g. an organic polymer or small-molecule semiconductor) for the semiconductor channels.

One or more conductor patterns are formed on a support substrate 2, comprising e.g. a flexible plastic support film temporarily supported on a more rigid carrier by means of e.g. a releasable adhesive. The one or more conductor patterns define the source and drain conductors 4, 6 for the TFT device.

A self-assembled monolayer (not shown) of an organic charge-injection material is selectively formed on the one or more conductor patterns to facilitate the transfer of charge carriers between the organic polymer semiconductor 8 and the source conductor 4 and/or between the organic polymer semiconductor 8 and the drain conductor 6.

A layer of organic polymer semiconductor 8 is formed over the resulting upper surface, by e.g. a solution-processing technique such as spin coating followed by baking.

A layer of insulating, cross-linkable organic polymer material 10 is formed over the upper surface of the semiconductor layer, by e.g. a solution processing technique such as spin coating followed by baking, which provides a first gate dielectric layer in the finished TFT device.

An image of the two-dimensional pattern desired for the semiconductor layer is then projected onto the insulating, cross-linkable organic polymer layer 10 using light of a wavelength that induces cross-linking of the cross-linkable polymer material 10. This image projection may be done by exposure of the upper surface of the insulating, cross-linkable organic polymer 10 to light of the necessary wavelength through a photomask 7 including a pattern of cut-outs 11 corresponding to the desired pattern for the semiconductor layer, in a sheet of material 9 that is optically opaque at the cross-linking wavelength. The photomask 7 is placed in contact with the upper surface of the cross-linkable organic polymer 10 in the necessary aligned position relative to the above-mentioned one or more conductor patterns, and is taken off after exposure, for re-use.

After removing the photomask 7, the latent image in the insulating organic polymer 10 (i.e. the pattern of relatively soluble, non-crosslinked regions and relatively insoluble, cross-linked regions) is developed using a solvent in which the non-crosslinked regions (unexposed regions) are substantially more soluble than the cross-linked regions (exposed regions). This development process leaves a physical pattern 13 in the insulating organic polymer layer substantially corresponding to the pattern desired for the semiconductor layer, and which reveals the semiconductor layer 8 in the regions in which the semiconductor layer 8 is to be removed. No photoresist layer or other deposited layer is used to create this pattern 13.

The upper surface of the resulting intermediate product is then subjected to a treatment such as reactive ion etching (RIE) involving a plasma, which etches away exposed parts of the semiconductor layer, to create a semiconductor pattern 14, which may comprise a semiconductor island in the region of the semiconductor channel for the TFT device. The RIE treatment may also act to etch the cross-linked insulating organic polymer pattern 13, but the thickness of the insulating organic polymer is sufficient that a sufficiently large thickness of insulating organic polymer remains after RIE is carried out for a time duration sufficient to etch the entire thickness of the semiconductor layer 8 in uncovered regions. The cross-linked insulating organic polymer pattern 13 functions as the uppermost (and only) protective mask in this semiconductor patterning process, protecting portions of the semiconductor layer 8 from etching. The creation of this semiconductor pattern 14 does not involve depositing any photoresist material or other patterning material on the first gate dielectric layer 10 by any liquid or vapour deposition technique.

A second layer 16 of the same insulating organic polymer material (or a different insulating organic polymer material) is then formed over the upper surface of the resulting intermediate product, by e.g. a solution-processing technique such as spin-coating followed by baking, which second layer provides a second gate dielectric layer in the finished TFT device.

One or more conductor patterns defining at least the gate conductor for the TFT device is formed on the upper surface of the second gate dielectric layer 16. Each conductor pattern may, for example, be formed by: (i) depositing conductive material (e.g. metal) on the upper surface of the gate dielectric through a shadow mask by e.g. a vapour deposition technique such as sputtering. A conductor pattern defining the gate conductor 18 for the TFT device may be achieved by e.g. depositing conductive material by a vapour deposition technique through a mask.

The above example of a set of processes according to one example of an embodiment of the present invention may be supplemented by one or more additional processes. For example, the second gate dielectric layer 16 may be patterned before forming the overlying conductor, in order to e.g. create via holes through which the overlying conductor creates interlayer conductive connections down to one or more conductor elements at the source-drain conductor level, such as a connection from the gate conductor down to a conductive element at the source-drain conductor level. This patterning of the second gate dielectric layer may, for example, be carried out using the same process as that used to pattern the first gate dielectric layer 10 (i.e. curing/cross-linking of a photo-patternable/cross-linkable insulating organic polymer in selected regions, followed by development using a solvent in which the cross-linked portions are substantially less soluble than the non-cross-linked portions).

As mentioned above, the same technique can also be used to construct a stack of layers defining an array of TFTs, in which e.g. the one or more conductor patterns at the source-drain level define (a) a set of source conductors each providing the source electrodes for a respective row of TFTs and each extending to a location outside the array for connection to a respective output terminal of a source driver chip, and (b) a respective drain conductor for each TFT; and the one or more conductor patterns at the gate level define a set of gate conductors each providing the gate electrode for a respective column of TFTs and each extending to a location outside the array for connection to a respective output terminal of a gate driver chip.

In addition to the technical finding that the omission of resist deposition and stripping processes lead to an improvement in TFT performance, it is also surprising that the exposure of the first gate dielectric layer to the RIE plasma in the region of the semiconductor channel of the TFT (as part of the process of patterning the semiconductor) does not critically effect the TFT performance.

In one variation, the RIE process used to remove exposed parts of the semiconductor layer 8 may be replaced by a process using a solvent in which the semiconductor is substantially more soluble than the cross-linked organic polymer of the first gate dielectric layer 10.

In addition to any modifications explicitly mentioned above, it will be evident to a person skilled in the art that various other modifications of the described embodiment may be made within the scope of the invention.

The applicant hereby discloses in isolation each individual feature described herein and any combination of two or more such features, to the extent that such features or combinations are capable of being carried out based on the present specification as a whole in the light of the common general knowledge of a person skilled in the art, irrespective of whether such features or combinations of features solve any problems disclosed herein, and without limitation to the scope of the claims. The applicant indicates that aspects of the present invention may consist of any such individual feature or combination of features.

1. A method, comprising:
forming, over a substrate comprising at least source and drain conductors for one or more transistor devices, at least a first, semiconductor layer providing one or more semiconductor channels for the one or more transistor devices;
forming, over the first layer, a second layer that defines at least part of a gate dielectric for the one or more transistor devices;
creating a pattern in the second layer, without depositing any temporary material onto the second layer; and
using the pattern in the second layer to pattern the first layer.

2. The method according to claim 1, wherein creating a pattern in the second layer, comprises:
exposing the second layer to an image of the pattern to create a solubility pattern in the second layer, the solubility pattern defining differences in solubility in a first solvent between different regions of the second layer; and
using the first solvent to develop the solubility pattern and create a physical pattern in the second layer.

3. The method according to claim 1, wherein using the pattern in the second layer to pattern the first layer comprises using a plasma treatment.

4. The method according to claim 2, wherein the exposing the second layer to an image of the pattern comprises exposing the second layer to a positive image of the pattern using radiation that decreases the solubility of the second layer in exposed regions.

5. The method according to claim 2, wherein the exposing the second layer to an image of the pattern comprises exposing the second layer to a positive image of the pattern using radiation of a wavelength that initiates a cross-linking reaction in the second layer in exposed regions.

6. The method according to claim 2, comprising forming at least one further insulating layer over the patterned, second layer; and forming over the at least one further insulating layer at least a gate conductor pattern defining at least gate conductors for the one or more transistor devices.

7. The method according to claim 6, wherein forming the gate conductor pattern comprises depositing conductor material onto the at least one further insulating layer through a shadow mask.

8. A method, comprising:
forming, over a substrate comprising at least source and drain conductors for one or more transistor devices, at least a first, semiconductor layer providing one or more semiconductor channels for the one or more transistor devices;
forming, over the first layer, a second layer comprising an insulating organic polymer material;
creating a pattern in the second layer, without depositing any temporary material onto the second layer; and using the pattern in the second layer to pattern the first layer;
forming over the patterned second layer a third layer also comprising the insulating organic polymer material; and
forming over the third layer at least a gate conductor pattern defining at least gate conductors for the one or more transistor devices; wherein the second and third layers together provide a gate dielectric for the one or more transistor devices.

9. The method according to claim 8, comprising creating a pattern in the third layer using the same process as that used to create the pattern in the second layer.

10. The method according to claim 8, comprising depositing the second and third layers by a solution-processing technique.

11. The method according to claim 8, wherein creating a pattern in the second layer, comprises:
exposing the second layer to an image of the pattern to create a solubility pattern in the second layer, the solubility pattern defining differences in solubility in a first solvent between different regions of the second layer; and
using the first solvent to develop the solubility pattern and create a physical pattern in the second layer.

12. The method according to claim 8, wherein using the pattern in the second layer to pattern the first layer comprises using a plasma treatment.

13. The method according to claim 8, wherein the exposing the second layer to an image of the pattern comprises exposing the second layer to a positive image of the pattern using radiation that decreases the solubility of the second layer in exposed regions.

14. The method according to claim 11, wherein the exposing the second layer to an image of the pattern comprises exposing the second layer to a positive image of the pattern using radiation of a wavelength that initiates a cross-linking reaction in the second layer in exposed regions.
